(19) United States
(12) Patent Application Publication
(10) Pub. No.: US 2006/0279938 A1
(43) Pub. Date: Dec. 14, 2006

(54) Apparatus for fastening a peripheral device

(75) Inventor: Wen-Cheng Tsai, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ASUSTeK Computer Inc.

(21) Appl. No.: 11/402,441

(22) Filed: Apr. 12, 2006

(30) Foreign Application Priority Data
May 17, 2005 (TW) 94115959

(51) Int. Cl. H05K 7/16

(52) U.S. Cl. 361/725

(57) ABSTRACT

An apparatus for fastening a peripheral device includes a chassis and a fastening unit. The chassis includes a second opening, a first fixing portion and a first pivotal portion. The fastening unit includes a first locking portion for passing through the second opening and then locking in the first opening to fasten a peripheral device onto the chassis. The first connecting portion is connected with the first locking portion and is pivoted at the first pivotal portion. The second fastening portion for locking into the first fastening portion is connected with the first connecting portion.

### RELATED APPLICATIONS

The present application is based on, and claims priority from, Taiwan Application Serial Number 94115959, filed May 17, 2005, the disclosure of which is hereby incorporated by reference herein in its entirety.

### BACKGROUND

1. Field of Invention

The present invention relates to an apparatus for fastening. More particularly, the present invention relates to an apparatus for fastening a peripheral device quickly.

2. Description of Related Art

With great developments of information technology, computer products have become increasingly more popularized. Specifically, various kinds of peripheral devices for a computer such as hard disk drives, floppy drives and CD-ROMs have become basic requirements for a computer system. The ever increasing quantity of peripheral devices in a computer system results in complicated installation and removal.

Typically, screws are used for fastening a peripheral device. However, using screws for fastening requires an auxiliary tool such as a screwdriver, and a large amount of screws are consumed, making the installation of the peripheral device inefficient. Therefore, the conventional way of using screws is not only inconvenient for device maintenance but reduces the maintenance efficiency.

Use of screws also causes some problems, like short circuits when screws are left inside the chassis, and screws may be lost after removal.

For the foregoing reasons, there is a need for a fastening apparatus that provides correct positioning and is convenient to operate so that the problems of conventional screw fastening are avoided.

### SUMMARY

It is therefore an objective of the present invention to provide an apparatus on which a peripheral device can be installed quickly without auxiliary tools.

It is another objective of the present invention to provide an apparatus on which a peripheral device can be installed quickly for installing or removing a computer peripheral device quickly and conveniently so that efficiencies of installation and maintenance are improved.

In accordance with the foregoing and other objectives of the present invention, an apparatus for fastening a peripheral device is provided. The apparatus includes a chassis and a fastening unit. The chassis has a second opening, a first fastening portion and a first pivotal portion. The fastening unit includes a first locking portion, a first connecting portion and a second fastening portion. The first locking portion passes through the second opening and into a first opening of the peripheral device for fastening the peripheral device. The first connecting portion is connected to the first locking portion and pivoted at the first pivotal portion. The second fastening portion for locking into the first fastening portion is connected with the first connecting portion.

In a preferred embodiment, the fastening unit is made of wire, and the first locking portion is formed as a hook.

The second fastening portion includes a third opening and the first fastening portion is a protrusion. Due to a connection between the first locking portion and the second fastening portion, when the fastening unit is rotated to allow the first locking portion to enter into the first opening to hold the device, the second fastening portion locks into the first fastening portion by the third opening. That way, the peripheral device is fastened and constrained in more than one direction. The fastening location can also be changed easily because the first connecting portion is able to slide in the first pivotal portion.

In conclusion, the apparatus of the present invention provides a simpler, faster and more convenient way of fastening a peripheral device than the conventional screw fastening. With the fastening unit of simple structure and the opening that is easy to establish, cost of production is low. A particular auxiliary tool and repeated action of screwing are not required to install or remove the peripheral device, so that installation and maintenance efficiencies are raised and time and effort are saved, too. Moreover, the present invention provides a variety of fastening locations and great extensibility.

It is to be understood that both the foregoing general description and the following detailed description are by examples and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1A is a schematic diagram of an apparatus for fastening a peripheral device in accordance with a preferred embodiment of the present invention;

FIG. 1B is a schematic diagram of a fastening unit in accordance with a preferred embodiment of the present invention;

FIG. 2 is a schematic diagram of an apparatus for fastening a peripheral device in accordance with another preferred embodiment of the present invention; and

FIG. 3 is a schematic diagram of a computer chassis with peripheral devices.

### DESCRIPTION OF THE PREFERRED EMBODIMENTS

The present invention discloses an apparatus for quickly installing and removing a peripheral device, involving no specific auxiliary tools and also providing a great selectivity of securing the devices at various positions. Reference will now be made in detail to the present preferred embodiments of the invention, examples of which are illustrated in the accompanying drawings. Wherever possible, the same reference numbers are used in the drawings and the description to refer to the same or like parts.

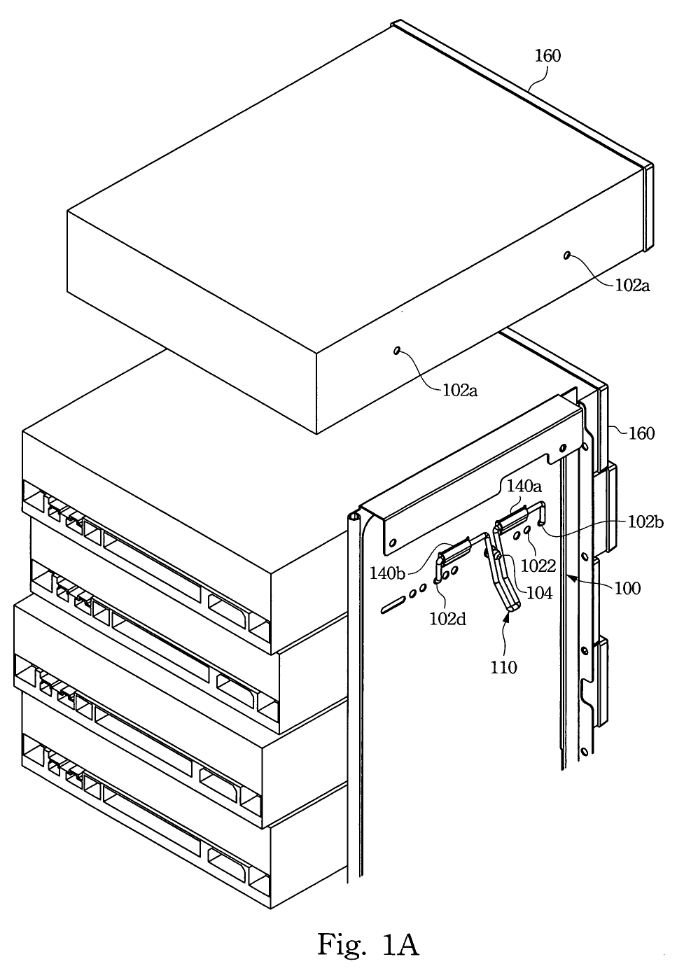

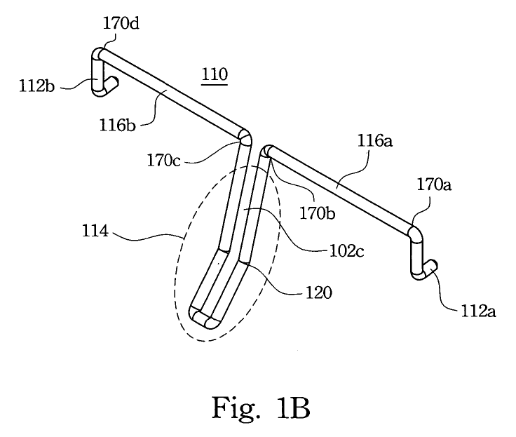

Referring to FIG. 1A and FIG. 1B. FIG. 1A is a schematic diagram of an apparatus for fastening a peripheral device in accordance with a preferred embodiment of the present invention. FIG. 1B is a schematic diagram of a fastening unit in accordance with a preferred embodiment of the present invention. FIG. 1B shows clearly that a fastening unit 110 includes a first locking portion 112a, a second fastening portion 114 and a first connecting portion 116a. The second fastening portion 114 has a bend 120 for conveniently rotating the fastening unit 110.

The apparatus for fastening a peripheral device includes a chassis 100 and a fastening unit 110. The chassis 100. for accommodating a peripheral device 160 includes a second opening 102b, a first fastening portion 104 and a first pivotal portion 140a. The peripheral device 160 has at least a first opening 102a. The fastening unit 110 includes a first locking portion 112a, a first connecting portion 116a and a second fastening portion 114. The first locking portion 112a is for passing through the second opening 102b and locking in the first opening 102a to hold the peripheral device 160 constrainedly. The first connecting portion 116a is connected to the first locking portion 112a and pivoted at the first pivotal portion 140a. The second fastening portion 114 connected to the first connecting portion 116a is for locking into the first fastening portion 104.

In a preferred embodiment, the first connecting portion 116a of the fastening unit 110 includes a first end 170a connected between the second fastening portion 114 and the first locking portion 112a. The fastening unit 110, for example, is made of steel wire, and the first locking portion 112a is formed as a hook.

The chassis 100 includes a first pivotal portion 140a accommodating the first connecting portion 116a and allowing the fastening unit 110 to pivot on it. The first connecting portion 116a is a cylindrical structure and is connected with both of the first locking portion 112a and a second end 170b. The second fastening portion 114 has a third opening 102c for engaging with the first fastening portion 104, for example, a U-shaped structure with a center opening or a structure with a hole.

The first fastening portion 104 is a protrusion and can be set on the chassis 100 by riveting, welding, bolting, screwing or other equivalent fastening manners. Preferably, at least a portion of the first fastening portion 104 shrinks towards the chassis 100 for constraining the second fastening portion 114, for example, a concave groove is formed around the middle of the first fastening portion 104, or the first fastening portion 104 may be a tapered or stepped structure.

When the peripheral device 160 such as a CD-ROM, a hard disk drive or a floppy drive is to be fastened, the peripheral device 160 is first put in a predetermined position according to need so that a first opening 102a of the peripheral device 160 is aligned with the second opening 102b. The second opening 102b can be a round hole, preferably an elliptic opening for providing more selections in fastening location and convenience of manufacturing.

And then the fastening unit 110 is rotated to allow the third opening 102c of the second fastening portion 114 to fit with the first fastening portion 104. By a close fit between the first fastening portion 104 and the third opening 102c, which is smaller than the width of the first fastening portion 104, the second fastening portion 114 is constrained, preferably in the narrower portion of the first fastening portion 104. The third opening 102c may also exert a force to clamp the first fastening portion 104 when fitting with it. At the same time, the first locking portion 112a enters through the second opening 102b and into the first opening 102a of the peripheral device 160.

The first locking portion 112a applies a holding force to hold and constrain the peripheral device 160. Therefore, the peripheral device 160 is constrained simultaneously in the forward/backward direction as well as the top/bottom direction, which results in an excellent holding effect.

When the fastening location of the peripheral device 160 is to be changed, the fastening unit 110 is rotated to allow the second fastening portion 114 to be separated from engaging with the first fastening portion 104 so that the second fastening portion 114 is released from constraint. Then, the peripheral device 160 is moved to align the first opening 102a with an expansion opening 1022, and the first connecting portion 116a holding by the first pivotal portion 140a is moved to align the first locking portion 112a with the expansion opening 1022. Then the fastening unit 110 is rotated to allow the second fastening portion 114 to lock onto the first fastening portion 104 and also the first locking portion 112a to enter into the first opening 102a of the peripheral device 160 through the expansion opening 1022 to hold the device. Therefore, the fastening location is changed quickly without difficulty.

The fastening unit 110 further includes a second connecting portion 116b and a second locking portion 112b. The second connecting portion 116b is connected to a third end 170c of the second fastening portion 114, and the second locking portion 112b is connected to a fourth end 170d of the second connecting portion 116b. The chassis 100 further includes a fourth opening 102d and a second pivotal portion 140b. The second locking portion 112b is for locking in another first opening 102a after passing through the fourth opening 102d, and the second connecting portion 116b is pivoted at and accommodated in the second pivotal portion 140b.

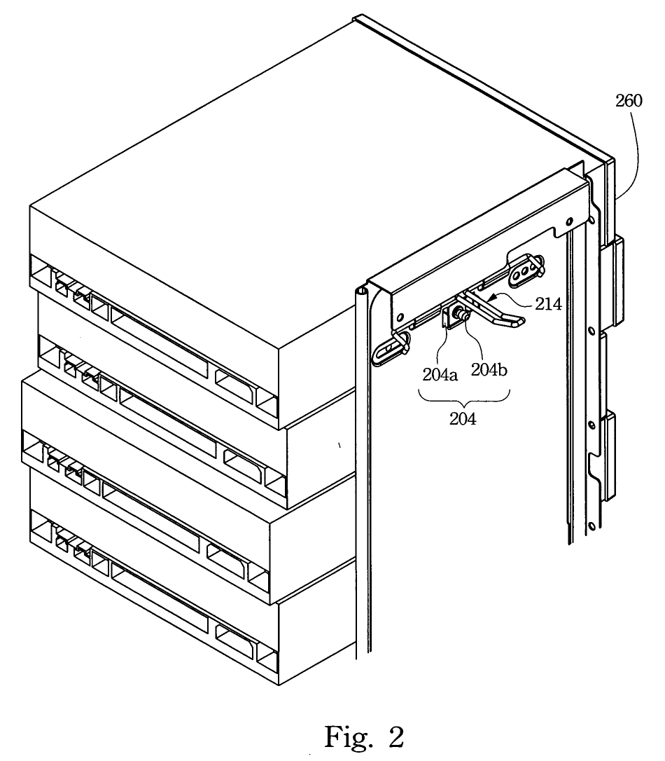

FIG. 2 is a schematic diagram of an apparatus for fastening a peripheral device in accordance with another preferred embodiment of the present invention, in which a first fastening portion 204 includes protrusions 204a and 204b for constraining or clamping a second fastening portion 214. Preferably, at least a protrusion is in a curved shape for constraining the second fastening portion 214. As shown in the figure, protrusions 204a and 204b are a curved plate and a protrudent bar respectively.

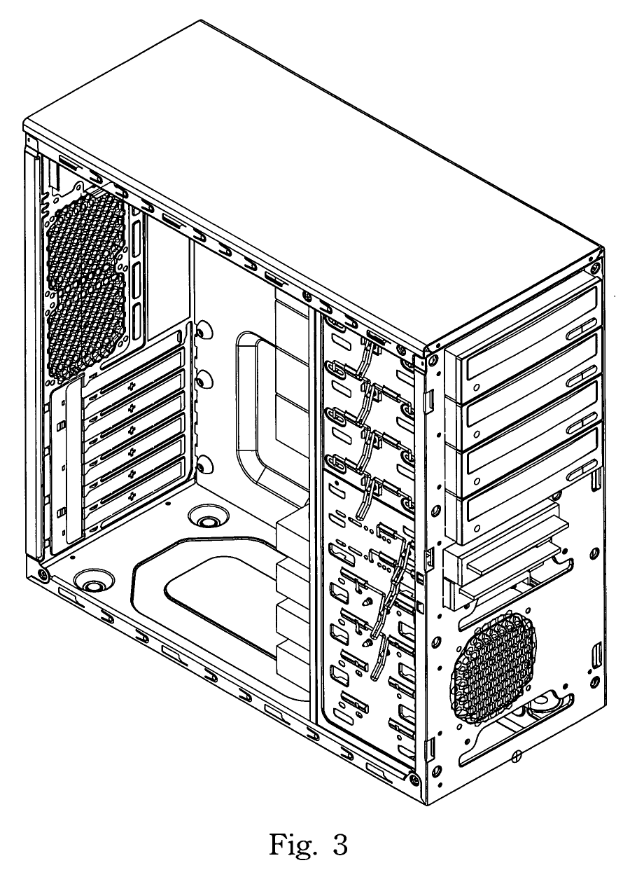

FIG. 3 is a schematic diagram of a computer chassis with peripheral devices. The figure shows that the present invention is applied in a chassis of a computer system and various versions of a first fastening portion are employed, that is, single protrusion and dual protrusions.

Alternatively, the first fastening portion may be a hollow structure disposed on the chassis forthe second fastening portion to lock into. Moreover, the second fastening portion is not required to be with a third opening above, as long as the first fastening portion and the second fastening portion are able to lock into each other.

The present invention has the following advantages. Through a fastening unit of simple structure and a second opening on the chassis, specific auxiliary tools are not required to install or remove a peripheral device. For low cost of manufacturing, the fastening unit can be made of steel wire and the first fastening portion may be a portion of the chassis.

In contrast with the conventional way of manually screwing the peripheral device onto the chassis, the present invention has a simple and convenient way of rotating the fastening unit to fasten or release the device by which installation and maintenance efficiencies are improved. Further, multiple fastening locations for the peripheral devices are available by establishing more second openings in positions desired.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for fastening a peripheral device with at least a first opening, comprising:
a chassis storing the peripheral device and having a second opening, a first fastening portion and a first pivotal portion; and
a fastening unit, comprising:
a first locking portion for passing through the second opening to lock in the first opening;
a first connecting portion connected to the first locking portion and pivoted at the first pivotal portion; and
a second fastening portion connected to the first connecting portion for locking into the first fastening portion.

2. The apparatus of claim 1, wherein the first fastening portion is a protrusion protruding from the chassis and having a concave in the middle for constraining the second fastening portion.

3. The apparatus of claim 1, wherein the second fastening portion comprises a third opening for clamping the first fastening portion.

4. The apparatus of claim 3, wherein the fastening unit is made of wire, the first locking portion is connected to a first end of the first connecting portion and is formed as a hook, the second fastening portion is a U-shaped structure with the third opening in the middle, and the first connecting portion is a cylindrical rod and is connected to the hook and a second end of the second fastening portion.

5. The apparatus of claim 3, wherein when the first fastening portion locks in the third opening, and the third opening exerts a force to clamp the first fastening portion.

6. The apparatus of claim 3, wherein the third opening is smaller than the first fastening portion.

7. The apparatus of claim 1, wherein the fastening unit further comprises a second connecting portion which is a cylindrical rod and is connected to a third end of the second fastening portion, and a second locking portion which is formed as a hook and is connected to a fourth end of the second connecting portion.

8. The apparatus of claim 7, wherein the chassis comprises a fourth opening and a second pivotal portion, the second locking portion passes through the fourth opening to lock in another first opening and the second connecting portion is pivoted at the second pivotal portion.
